(19) United States
(12) Patent Application Publication
(10) Pub. No.: US 2026/0332119 A1
(43) Pub. Date: Oct. 22, 2026

(54) MONOLITHIC TUNABLE BANDPASS FILTER FOR OUT-OF-BAND NOISE MITIGATION IN SUPERCONDUCTING QUANTUM SYSTEMS

(71) Applicant: Dell Products L.P., Round Rock, TX (US)

(72) Inventors: Navjot Kaur Khaira, Manotick (CA); Tejinder Singh, Manotick (CA)

(21) Appl. No.: 19/186,490

(22) Filed: Apr. 22, 2025

(51) Int. Cl. H03H 7/01; G06N 10/40

(52) U.S. Cl. CPC H03H 7/0161; G06N 10/40

(57) ABSTRACT

The technology described herein is directed towards a tunable bandpass filter capable of operating at cryogenic temperatures. The bandpass filter includes capacitors, and inductors inductively coupled to RF-SQUID sets. The amount of inductance is controllable by applying a voltage to a DC control line inductively coupled to the respective RF-SQUID sets, which in turn are inductively coupled to the inductors, respectively. The controllably tuned inductance adjusts the frequency band that the bandpass filter passes. The tunable device attenuates noise outside of passed microwave signal frequency band for a cleaner microwave signal directed for interaction with qubits, for example, and improves overall qubit stability. In one example implementation, a classical computing device can be used to monitor the qubits following qubit interaction with a microwave signal from a photon source, detecting any deviations or noise-induced errors. Based on the monitoring, the computing device can adjust the bandpass filter's passed frequency band.

### BACKGROUND

Quantum computing systems perform highly sensitive operations where even small amounts of noise can lead to significant errors during qubit manipulation. Traditional quantum systems, where signals from a photon source directly interact with the qubit chain, are particularly vulnerable to noise, resulting in decoherence and reduced gate fidelity. As quantum operations require long periods of coherence, errors introduced by noise and/or other environmental factors can accumulate, compromising quantum gate operations.

### BRIEF DESCRIPTION OF THE DRAWINGS

The technology described herein is illustrated by way of example and not limited to the accompanying figures in which like reference numerals indicate similar elements and in which:

FIG. 1 is a top view representation of an example tunable bandpass filter suitable for use with quantum hardware, e.g., with signal input from a microwave source and bandpass filtered output directed to qubits, in accordance with various example embodiments and implementations of the subject disclosure.

FIG. 2 is a zoomed-in representation of a portion the example tunable bandpass filter of FIG. 1 showing capacitors, and inductors tuned by radio-frequency superconducting quantum interference devices (RF-SQUIDs), in accordance with various example embodiments and implementations of the subject disclosure.

FIG. 3 is a circuit schematic representative of an example five-pole bandpass filter, generally corresponding to the tunable bandpass filter of FIG. 1, showing five capacitors and two inductors, in accordance with various example embodiments and implementations of the subject disclosure.

FIG. 4 is a three-dimensional (3D) representation of an example tunable bandpass filter layout, in accordance with various example embodiments and implementations of the subject disclosure.

FIGS. 5A and 5B are zoomed-in representations of portions of the example tunable bandpass filter of FIG. 4, highlighting various components such as rf-SQUID coupled inductors and multilayer capacitors, in accordance with various example embodiments and implementations of the subject disclosure.

FIGS. 6A and 6B are zoomed-in representations of portions of the example tunable bandpass filter of FIG. 4, highlighting various components such as multilayer capacitors, interconnects between layers and rf-SQUIDs, in accordance with various example embodiments and implementations of the subject disclosure.

FIG. 7 is a top view representation of an example compact, tunable bandpass filter layout in which tuning of the bandpass filter is achieved by using an array of rf-SQUIDs, in accordance with various example embodiments and implementations of the subject disclosure.

FIG. 8 is a graphical representation of simulated reflection magnitude (S₁₁ reflection characteristics) versus frequency for one example tunable bandpass filter, in accordance with various example embodiments and implementations of the subject disclosure.

FIG. 9 is a graphical representation of simulated transmission magnitude of the example tunable bandpass filter versus frequency for one example tunable bandpass filter, in accordance with various example embodiments and implementations of the subject disclosure.

FIG. 10 is a block diagram representation of an example a hybrid classical-quantum system in which a tunable bandpass filter is deployed in a dilution refrigerator before a qubit chain to filter a microwave signal directed towards the qubit chain, in accordance with various example embodiments and implementations of the subject disclosure.

FIGS. 11 and 12 depict an example hybrid classical-quantum system for controlling and measuring qubit operations, including via selectively tuned bandpass filtering of signal to qubits via a cryogenic tunable bandpass filter, in accordance with various example embodiments and implementations of the subject disclosure.

FIG. 13 is a conceptual representation of a quantum computer including a dilution refrigerator with qubits and a cryogenic tunable bandpass filter operating at qubit temperatures, in accordance with various example embodiments and implementations of the subject disclosure.

FIG. 14 is a flow diagram showing example operations related to controlling a tunable bandpass filter to output a filtered radio frequency signal, in accordance with various example embodiments and implementations of the subject disclosure.

### DETAILED DESCRIPTION

The technology described herein is generally directed towards cryogenic bandpass filters that function by allowing only a specific range of frequencies to pass through while attenuating signals outside this range. In general, bandpass filters are significant components in quantum computers, particularly those using superconducting qubits, which are typically designed to operate at specific frequencies within the microwave range, with the most popular being 4 GHz-12 GHz. As quantum computers require extremely clean and precise microwave signals in this frequency range, bandpass filters help eliminate unwanted signals and noise outside this band, ensuring that only the desired frequencies reach the qubits, which helps to maintain the coherence of the qubits. Additionally, in dispersive readout methods, the bandpass filters help in isolating the readout signal from any interference or noise, improving the accuracy and sensitivity of qubit state measurement. Bandpass filters also help to attenuate noise from frequencies outside the desired range, which is significant for maintaining low-noise, high-fidelity quantum operations.

Described herein is a tunable microstrip-based bandpass filter, based on the integration of rf-SQUIDs for fine-tuning the filter response. Further, a monolithic integration approach allows the bandpass filter to be fabricated in an extremely compact design, which can be on the same chip as the qubits, thereby occupying less space than traditional external filters. By offering monolithic integration, tunability, and a compact footprint, the bandpass filter described herein reduces system complexity, and facilities greater flexibility in advanced multi-qubit systems.

Note that the currently used waveguide-based bandpass filters in quantum computers have disadvantages, including thermal management, because external filters can contribute to thermal load within the cryogenic system. Managing this additional heat becomes challenging, especially because any increase in temperature can negatively affect qubit coherence times. Further, quantum systems are often limited by space, particularly when they are scaled up to include many qubits; external filters occupy valuable space within the cryogenic environment, making it harder to achieve the necessary compactness and integration for large scale quantum systems. Still further, most conventional bandpass filters used in quantum computing are not tunable, meaning they operate at fixed frequencies. As qubits can experience frequency shifts due to fabrication variations or environmental factors, fixed filters may not align perfectly with the desired qubit frequencies, leading to suboptimal filtering and potential crosstalk. At the same time, the need to interface external filters with the quantum chip adds complexity to the system design and assembly.

Indeed, existing microwave bandpass filters for quantum systems predominantly include waveguide-based filters and lumped element filters that are used to control the frequency range within which superconducting qubits operate. These filters are typically designed for fixed frequencies, and serve to eliminate out-of-band noise and interference. Traditional waveguide filters can be effective in offering low loss and precise frequency selection, but they come with limitations such as large physical size, which is problematic in the compact environments of quantum computers. Lumped element filters, while more compact, often lack the precision and tunability needed for advanced quantum systems. Further, both types of filters contribute to thermal load in cryogenic setups, and their lack of tunability poses challenges when qubits experience frequency shifts due to fabrication imperfections or environmental factors. Many designs still rely on external interfacing, which can introduce additional signal losses and complexity.

The microstrip-based tunable bandpass filter technology described herein, which can be monolithically integrated on the same chip as the qubits, overcomes these current disadvantages, including by eliminating the need for lossy connections, thereby significantly reducing signal losses, and maintaining higher signal integrity. Monolithic integration reduces the complexity of system design and assembly. This directly translates to better qubit performance and more reliable quantum operations. Notwithstanding, the tunable bandpass filter device described herein can also be used at room temperatures, or even higher.

Reference throughout this specification to “one embodiment,” “an embodiment,” “one implementation,” “an implementation,” etc. means that a particular feature, structure, characteristic and/or attribute described in connection with the embodiment/implementation can be included in at least one embodiment/implementation. Thus, the appearances of such a phrase “in one embodiment,” “in an implementation,” etc. in various places throughout this specification are not necessarily all referring to the same embodiment/implementation. Furthermore, the particular features, structures, characteristics and/or attributes may be combined in any suitable manner in one or more embodiments/implementations. Repetitive description of like elements employed in respective embodiments may be omitted for sake of brevity.

The detailed description is merely illustrative and is not intended to limit embodiments and/or application or uses of embodiments. Furthermore, there is no intention to be bound by any expressed or implied information presented in the preceding sections, or in the Detailed Description section. Further, it is to be understood that the present disclosure will be described in terms of a given illustrative architecture; however, other architectures, structures, materials and process features, and steps can be varied within the scope of the present disclosure.

It also should be noted that terms used herein, such as “optimize,” “optimization,” “optimal,” “optimally” and the like only represent objectives to move towards a more optimal state, rather than necessarily obtaining ideal results. Similarly, “maximize” means moving towards a maximal state (e.g., up to some processing capacity limit), not necessarily achieving such a state, and so on.

It will also be understood that when an element such as a layer, region or substrate is referred to as being “on” or “over” “atop” “above” “beneath” “below” and so forth with respect to another element, it can be directly on the other element or intervening elements can also be present. In contrast, only if and when an element is referred to as being “directly on” or “directly over” another element, are there no intervening element(s) present. Note that orientation is generally relative; e.g., “on” or “over” can be flipped, and if so, can be considered unchanged, even if technically appearing to be under or below/beneath when represented in a flipped orientation. It will also be understood that when an element is referred to as being “connected” or “coupled” to another element, it can be directly connected or coupled to the other element or intervening elements can be present. In contrast, only if and when an element is referred to as being “directly connected” or “directly coupled” to another element, are there no intervening element(s) present.

The following detailed description is merely illustrative and is not intended to limit embodiments and/or application or uses of embodiments. Furthermore, there is no intention to be bound by any expressed or implied information presented in the preceding sections, or in the Detailed Description section.

One or more example embodiments are now described with reference to the drawings, in which example components, graphs and/or operations are shown, and in which like referenced numerals are used to refer to like elements throughout. In the following description, for purposes of explanation, numerous specific details are set forth in order to provide a more thorough understanding of the one or more embodiments. It is evident, however, in various cases, that the one or more embodiments can be practiced without these specific details, and that the subject disclosure may be embodied in many different forms and should not be construed as limited to the examples set forth herein.

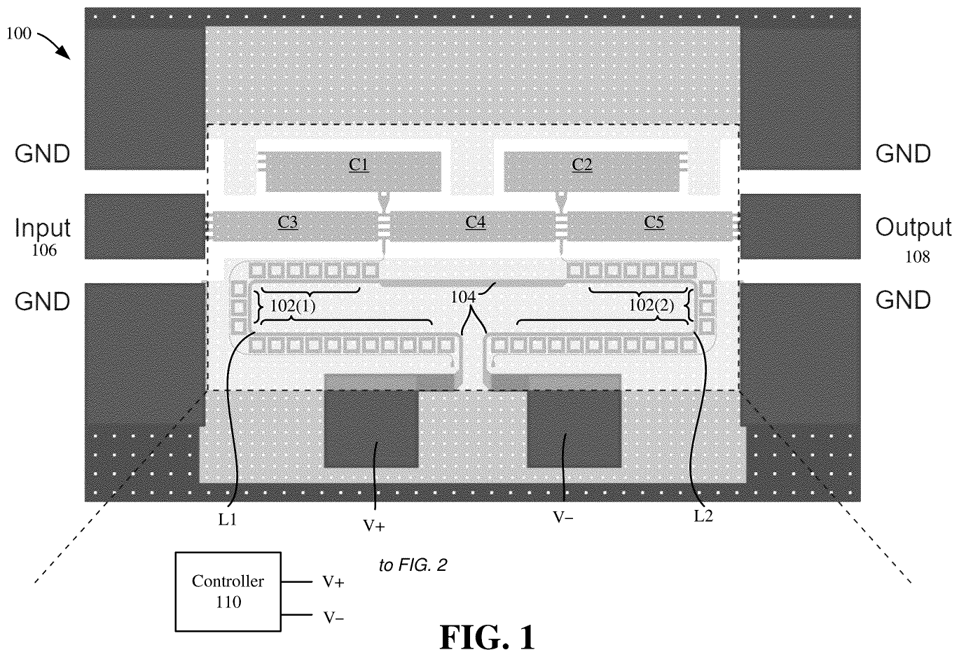

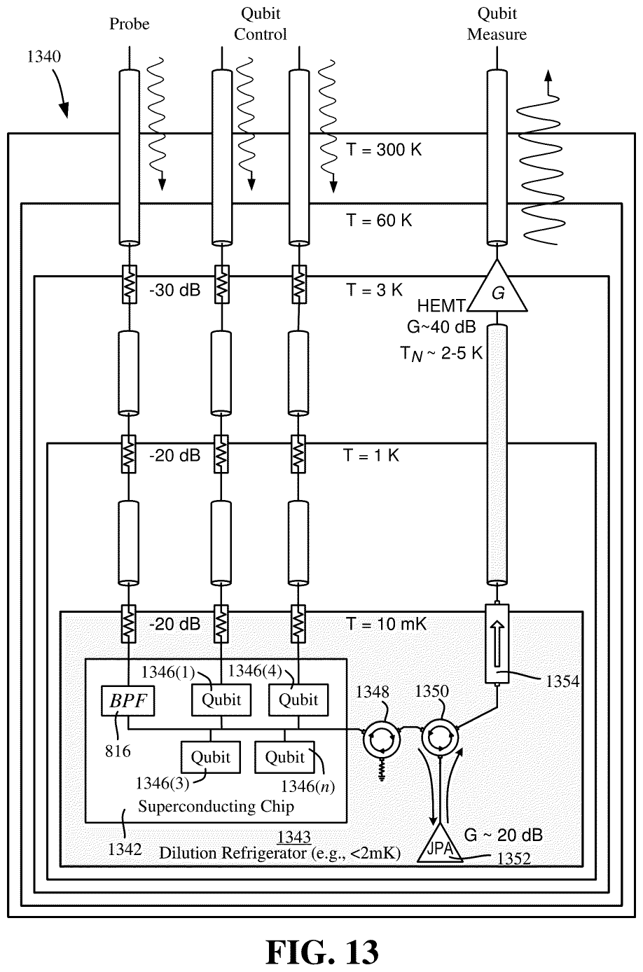

FIG. 1 shows one example of a microwave signal tunable bandpass filter 100 (FIGS. 1-7) suitable for use at cryogenic temperatures. In general, the tunable bandpass filter 100 described herein is directed to a bandpass filter with precise filtering control based on radio-frequency superconducting quantum interference device (RF-SQUIDs)-based superconducting. The example device can be deployed in a dilution refrigerator, and indeed, (as in FIG. 13), can be monolithically integrated on the same chip as the qubits, e.g., optimized for operation at extremely low cryogenic temperatures of around 2 mK.

Superconducting qubits are typically designed to operate at specific frequencies within the microwave range, with the most popular being 4 GHZ-12 GHZ. In general, a bandpass filter can be used to filter out frequencies that are not within a specific frequency band, such as noise, corresponding to an undesirable frequency or frequencies, that is associated with a microwave signal directed to a qubit.

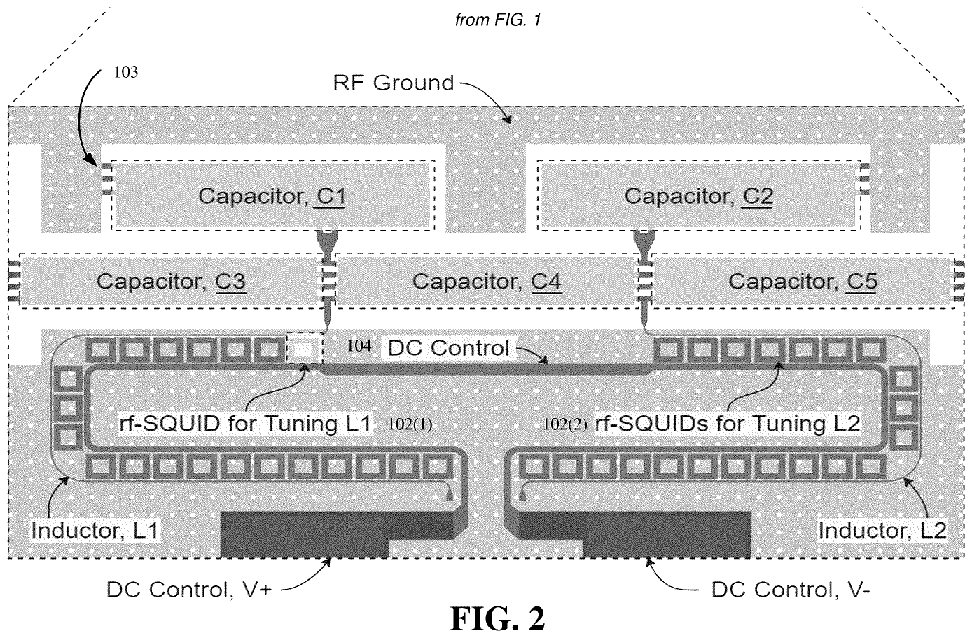

FIG. 1 along with the zoomed-in portion thereof in FIG. 2 shows the physical arrangement of the components on the bandpass filter (device) 100 layout in one example implementation. A multilayer metal-insulator-metal (MIM) capacitor design, also known as parallel plate capacitors, is used to keep the capacitors C1-C5 compact while maintaining high capacitance values. The capacitor plates can be formed from multiple thin niobium layers, separated by dielectric layers of e.g., silicon dioxide (SiO₂). Inductors L1 and L2 are realized using microstrip lines and are made tunable by placing an array of rf-SQUIDs 102(1) and 102(2), respectively, in close proximity along the microstrips, resulting in mutual flux coupling zones. The capacitors are coupled to other components via sets of interconnects; one interconnect set 103 is labeled in FIG. 2.

ADC control line 104, coupled to contacts V+ and V−, runs alongside the rf-SQUIDs 102(1) and 102(2), and the current flowing through the control line 104 generates a magnetic flux that inductively couples with the rf-SQUIDs 102(1) and 102(2). The voltage-controlled varying magnetic flux alters the inductance of the rf-SQUIDs 102(1) and 102(2), effectively turning them into variable inductors. The mutual coupling between the rf-SQUIDs (acting as variable inductors) and the inductive microstrip lines L1 and L2 causes a change in inductance of L1 and L2. The magnitude of this inductance change depends on the voltage applied to the DC control line 104.

In this way, a radio frequency (RF) (e.g., microwave) signal from a microwave signal source obtained at the input (input coplanar waveguide (CPW) contact pad 106) travels through and is bandpass filtered by the filter 100 to the output CPW contact pad 108. Frequencies within the controllably tuned frequency band are passed, while those outside of the tuned frequency band are attenuated, resulting in a cleaner microwave signal. Note that a controller 110, which can be a classical computing device as described herein, tunes the bandpass filter 100 according to a specified frequency range, as appropriate for a given application, by applying the appropriate amount of controlled voltage bias across the DC control line 104.

To derive the expression for the change in inductance of the microstrip inductor when coupled with RF-SQUIDs, consider a microstrip unit cell, which in an equivalent circuit includes a shunt capacitance Cₘ and series inductance Lₘ, coupled to a superconducting loop with inductance L_{sq} and Josephson Junction (JJ) with inductance Lⱼ. The coupling between Lₘ and L_{sq} is defined by mutual coupling M₁ and coupling coefficient K₁. Additionally, a microstrip control transmission line, monolithically integrated on-chip, runs parallel to the RF-SQUIDs. The unit inductance of this control microstrip transmission line Lc couples to the SQUID loop inductance L_{sq} With mutual inductance M₂ and coupling coefficient K₂.

$$\begin{matrix}{K}_{1}^{2} = \frac{{M}_{1}^{2}}{{L}_{s q} {L}_{c}} ; & {K}_{2}^{2} = \frac{{M}_{2}^{2}}{{L}_{s q} {L}_{c}}\end{matrix} \qquad ( 1 )$$

The control current i_{dc} applied to the control line generates a magnetic field around the microstrip top conductor, inducing a geometrical flux φₑₓₜ in the SQUID loop:

φₑₓₜ=M₂i_{dc} (2)

A circulating current i_{sq} is induced in the SQUID loop to screen this flux, due to flux quantization condition, leading to the total flux φ_{sq} in the loop:

φ_{sq}=φₑₓₜ+L_{sq}i_{sq} (3)

The circulating supercurrent depends on the critical current I_{c} of the JJ and the total flux in the SQUID loop:

$${i}_{s q} = - {I}_{c} sin \frac{2 {πϕ}_{s q}}{{ϕ}_{0}} \qquad ( 4 )$$

where φ₀ is the flux quantum (φ₀=2.0679×10⁻¹⁵ Wb) and I_{c} is determined by the area of the junction A and the current density J_{c} of the junction. The behavior of the SQUID is characterized by the screening parameter of RF-SQUID given by:

$$β = \frac{2 π {L}_{s q} {I}_{c}}{{ϕ}_{0}} \qquad ( 5 )$$

For this application, the condition β<1 is satisfied, and the internal flux in the SQUID increases monotonically with the external flux φₑₓₜ.

SQUID inductance is a combination of the junction inductance and the inductance of the superconducting loop. The effective inductance controlled by modulating the magnetic flux threading the junction loop can be obtained as:

$${L}_{eff} = \frac{d {ϕ}_{e x t}}{{di}_{s q}} \qquad ( 6 )$$

Differentiating equation (3) with respect to iₛ

$$\frac{d {ϕ}_{e x t}}{{di}_{s q}} = - {L}_{s q} + \frac{1}{d {i}_{s q} / d {ϕ}_{e x t}} \qquad ( 7 )$$

Differentiating equation (4) with respect to φₛ

$$\frac{{di}_{s q}}{d {ϕ}_{e x t}} = - \frac{2 π {I}_{c}}{{ϕ}_{0}} cos ( \frac{2 {πϕ}_{s q}}{{ϕ}_{0}} ) \qquad ( 8 )$$

Combining equations (5), (6), (7) and (8),

$${L}_{eff} = {L}_{s q} + \frac{{L}_{s q}}{β cos ( 2 {πϕ}_{sq} ) / {ϕ}_{0}} \qquad ( 9 )$$

$${L}_{eff} = {L}_{s q} + {L}_{j} \qquad ( 10 )$$

where Lⱼ is the junction equivalent inductance.

$${L}_{j} = \frac{{L}_{s q}}{β cos ( 2 {πϕ}_{s q} ) / {ϕ}_{0}} \qquad ( 11 )$$

The effective inductance of the microstrip inductor

$${L}_{m}^{′}$$

coupled to the SQUID is influenced by the change in inductance from the RF-SQUIDs and the level of mutual coupling between the inductive microstrip and the four RF-SQUIDs.

$${L}_{m}^{′} = {L}_{m} [ 1 - \frac{{K}_{1}^{2} {L}_{s q}}{{L}_{j} + {L}_{s q}} ] = {L}_{m} [ 1 - \frac{{K}_{1}^{2}}{1 + ( \frac{1}{β} cos ( \frac{2 {πϕ}_{s q}}{{ϕ}_{0}} ) )} ]$$

The tunability in the inductance of the microstrip lines enabling precise control over the bandpass filter.

In one example implementation, as in FIG. 1 the bandpass filter is configured in a five-pole configuration, fabricated with a multilayer superconducting fabrication process that uses eight (e.g., Niobium) thin superconducting layers. Note that while five poles provide an advantageously clean response, the bandpass filter technology described herein is not limited to a five-pole device.

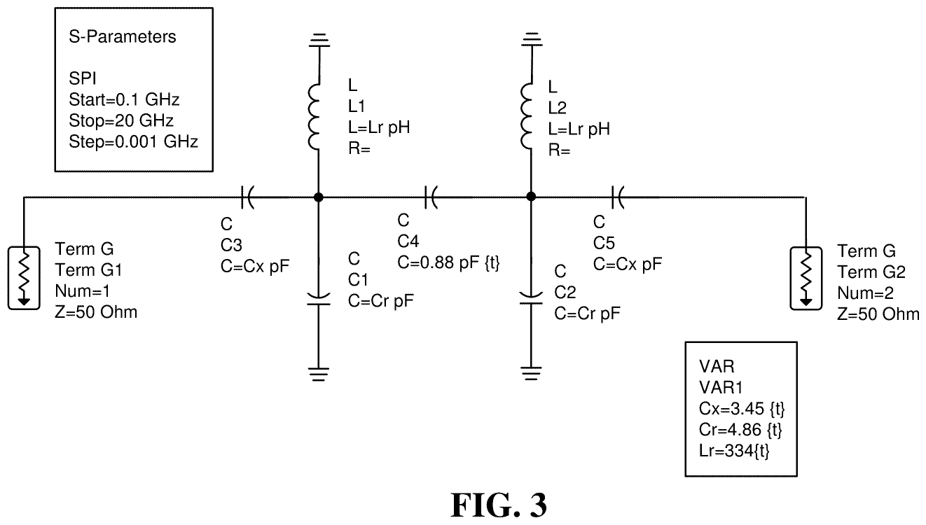

FIG. 3 shows a circuit schematic of an example five-pole bandpass filter, corresponding to FIG. 1, showing the five capacitors C1-C5 and two inductors L1 and L2. The circuit schematic demonstrates the bandpass filter components, including capacitors C1 to C5, inductors L1 and L2. In this implementation, the specific values of the components are selected to achieve the desired bandpass characteristics within the 4 GHz to 8 GHz range. The inductance value is kept variable to simulate the change in inductor value needed to achieve the desired tuning in the frequency response. Note that each capacitor C1 is C2 are shunted to ground at one end, and coupled to the inductors and other capacitors and the other end. One of the ends of each capacitor C1 and C5 are terminated by a fifty-ohm resistor to ground, and the inductors L1 and L2 are each coupled at one end to ground. The other ends of capacitor C1, capacitor C3 and inductor L1 are coupled to a first conductor. The other ends of capacitor C2, capacitor C5 and inductor L2 are coupled to a second conductor. The first and conductors are coupled together through capacitor C4.

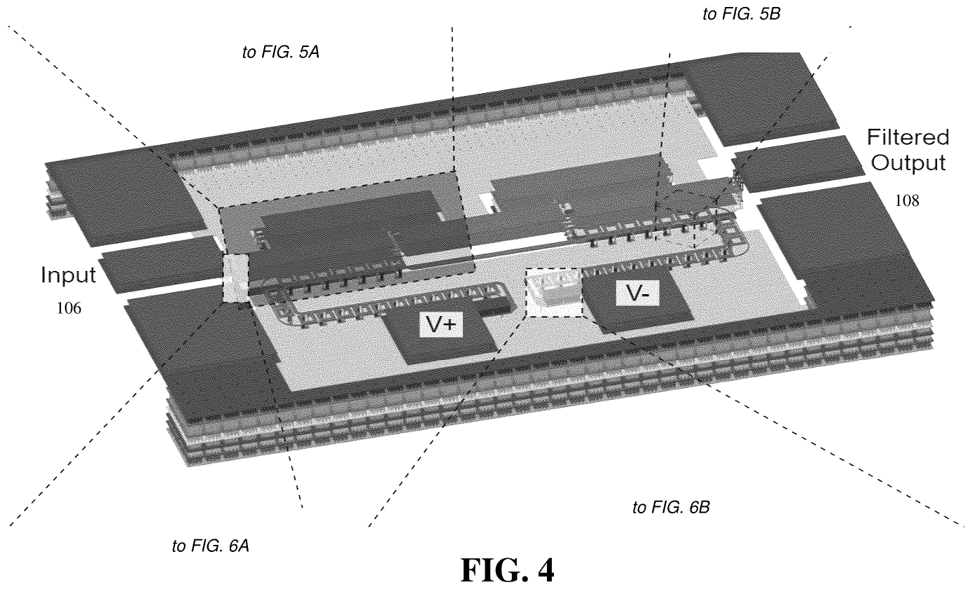

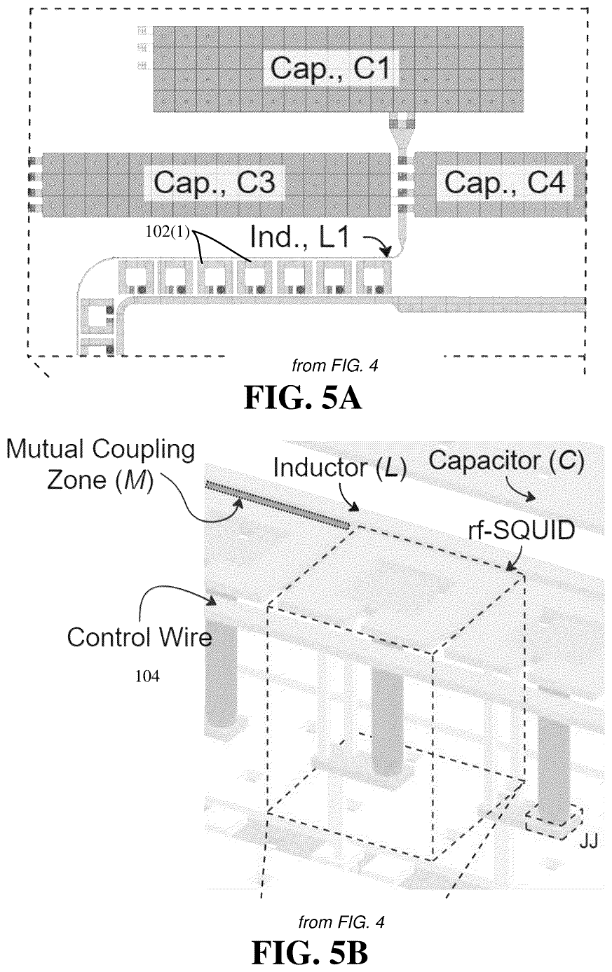

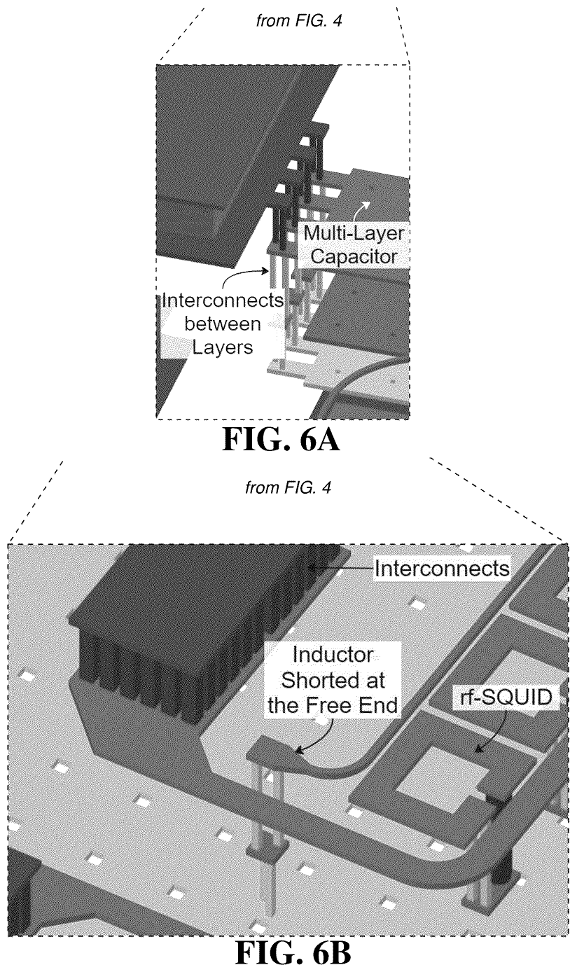

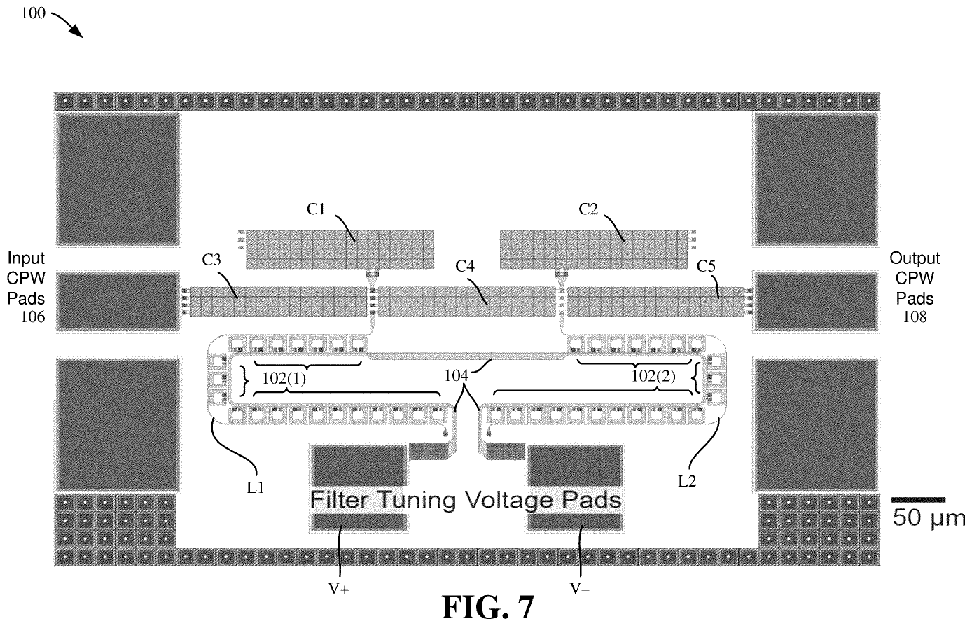

FIG. 4, along with the zoomed-in portions thereof in FIGS. 5A, 5B, 6A and 6B, present a three-dimensional (3D) view showing the multilayer layout for the example tunable bandpass filter. The inductors (L1 and L2) are shorted at the free end (FIG. 6B), with the tunability achieved via the control wire (FIG. 5B) and voltage applied across the V+ and V-contact pads, which modulates the magnetic flux in the rf-SQUIDs (FIGS. 5A and 5B), e.g., of the rf-SQUID array 102(1). The level of mutual coupling (M) between the inductor lines and the rf-SQUIDs increases as they are placed closer to each other. Multi-layer MIM capacitors (C1, C2, C3, C4 and C5) are used for compactness while maintaining the chosen capacitance values. The input and filtered output are accessed through designated input coplanar waveguide (CPW) pads 440 (FIGS. 4 and 7), with interconnections (FIG. 6A) between the superconducting layers facilitating seamless signal flow.

In one implementation, the bandpass filter is designed for monolithic integration of the filter onto the quantum chip (FIG. 13), which eliminates the need for external interconnects, significantly reducing signal losses and preserving signal integrity. This integration streamlines the overall system design, and also contributes to better thermal management by minimizing the heat load on the cryogenic system.

The bandpass filter design layout, as shown in FIG. 7, illustrates the compact and efficient use of space, significant for quantum systems where space is at a premium; a 50 micrometer (μm) length is depicted in this example to demonstrate the overall size of the example device. The filter 100 offers high precision in filtering specific frequency bands.

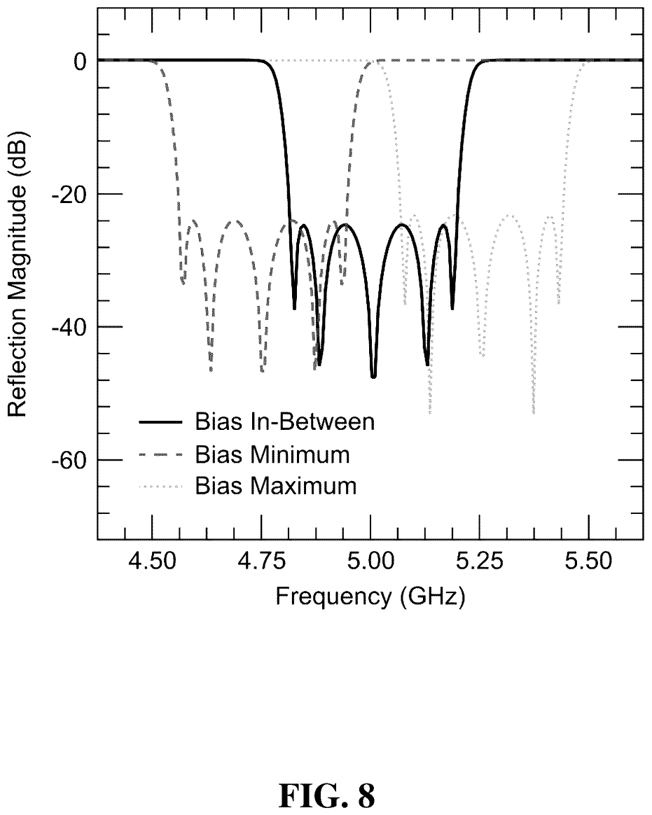

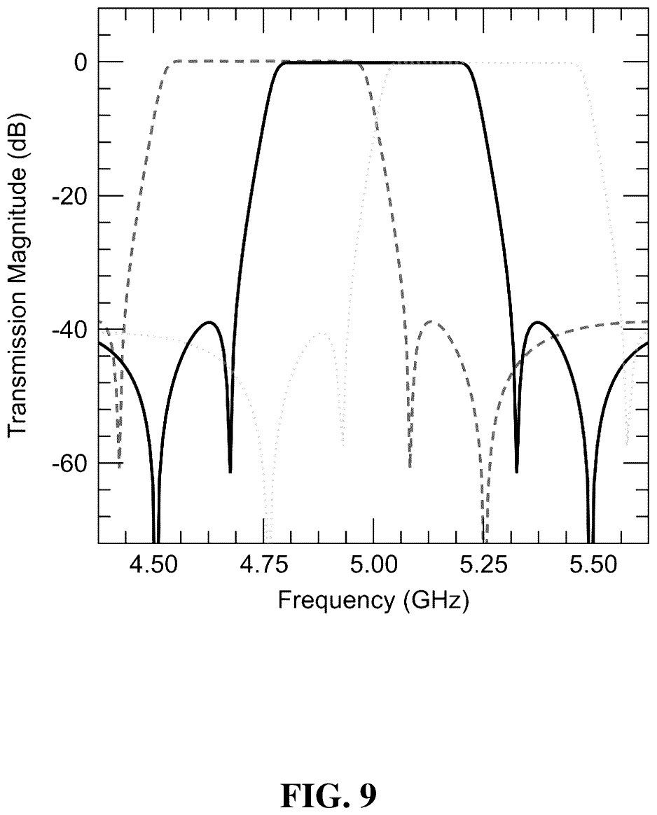

The performance of the example bandpass filter is validated through S-parameter simulations, as shown in the plots in FIGS. 8 and 9. FIG. 8 shows the filter's reflection characteristics across the frequency range. while FIG. 9 shows the filter's transmission characteristics. These S-parameter results demonstrate a well-defined passband with minimal insertion loss, which helps ensure that the only the microwave photons within the desired frequency band are transmitted to the qubits.

The solid, dotted and dashed curves in FIGS. 8 and 9 correspond to different tuning states, showing how the center frequency of the passband can be controllably shifted between states as different amounts of voltage are applied to the control line. The tunability of the filter allows for precise alignment with the qubit operating frequencies, reducing the risk of crosstalk and interference from unwanted signals.

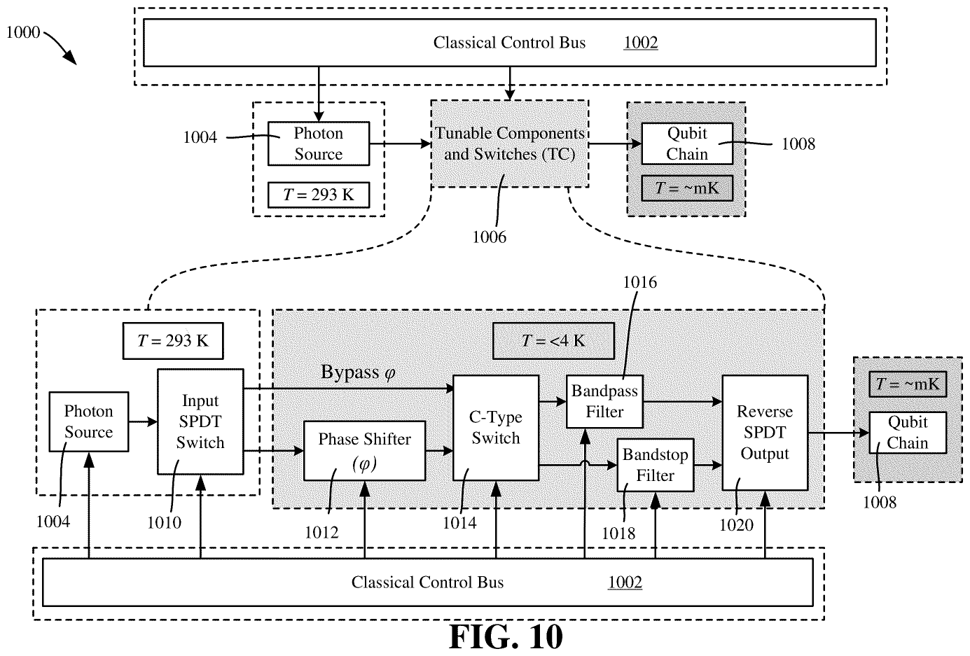

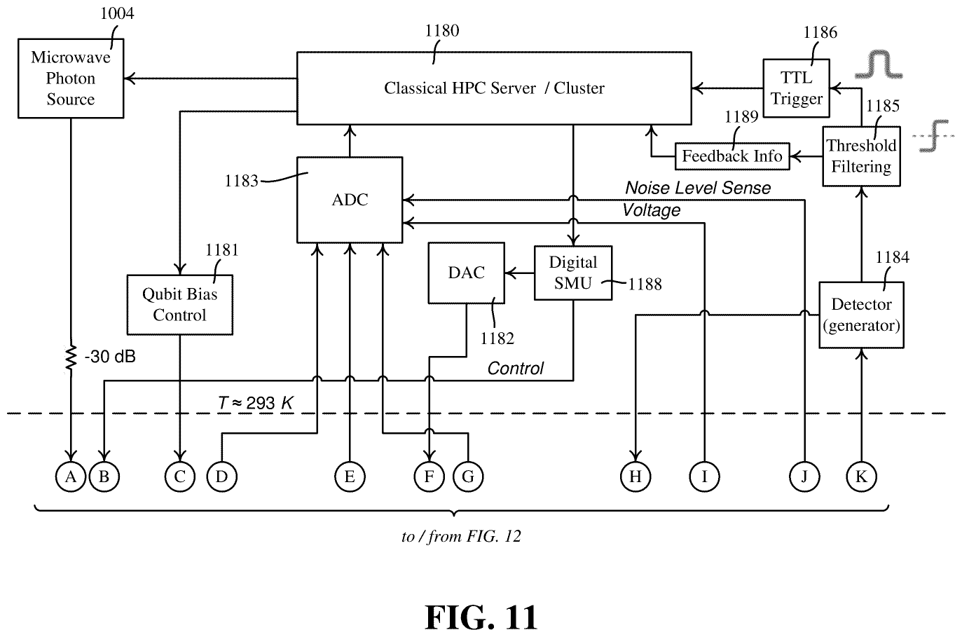

Turning to one example usage scenario, FIG. 10 is a generalized representation of an example hybrid classical-quantum system 1000 that includes a classical control bus 1002 (coupled to a classical computing device, e.g., FIG. 11) and a quantum circuit in which a photon source 1004, tunable components and switches (TC) 1006 and qubit chain 1008 interact with the benefit of intermediate tunable components 1006 as described herein. Note that the tunable components 1006 make the qubits less vulnerable to noise, thermal drift, or other forms of signal degradation; indeed, such signal issues can lead to errors in qubit manipulation, reducing gate fidelity.

The photon source 1004 generates the microwave signals used to manipulate qubits, as controlled by the computing device (the control bus 1002 of which is shown in FIG. 10); the temperature at this stage is room temperature (e.g., around 293 K). The tunable components and switches 1006 include an input single-pole, double throw (SPDT) switch 1010 controlled via the classical control bus 1002 to either bypass a phase shifter or shift the phase of the microwave signal via a phase shifter 1012 that operates at cryogenic temperatures (below 4 K in this example). The phase shifter 1012, if switched in, adjusts the phase of the microwave signals before they interact with the qubits of the qubit chain 1008; the phase shifter may be a tunable device. The placement at cryogenic temperatures helps reduce phase drift caused by thermal noise.

A controlled C-type switch 1014 selects a tunable (via the control bus 1002) bandpass filter 1016 (e.g., corresponding to the bandpass filter 100 of FIGS. 1-7) as described herein, and/or a bandstop filter 1018. A reverse SPDT switch 1020 couples the filtered signal to the qubit chain 1008.

The qubit chain 1008 includes qubits that are maintained at extremely low temperatures (millikelvin range) to ensure their stability/coherence during quantum gate operations. The signals from the photon source 1004 interact directly with the qubits, manipulating their quantum states. After interacting with the qubits, the signal can be amplified, and measured (e.g., at room temperature); the amplified and measured signals are processed at room temperature by the classical computing device, such as to adjust the phase shifter and/or filtering to correct for phase noise, frequency noise, and so on to maintain qubit coherence.

In general, the integration of the classical computing device (control node) can monitor the signals in real time, to detect any noise errors or deviations that arise due to external environmental factors or hardware imperfections. Because quantum gate operations are extremely sensitive to such noise-related variations, the classical computing device compares the incoming signals as measured and flags any discrepancies from what the signal should be without noise errors or the like. Upon detecting deviations, the control node dynamically adjusts the tunable components to correct the next signal before it interacts with the qubit chain, thereby minimizing the impact of noise on qubit operations.

Note that temperature control is a significant part of the quantum portion of the system, as different components operate at significantly different temperature levels to minimize noise and maintain coherence. The quantum processor operates at extremely low temperatures, with the qubit chain at 10 mK or below, and the signal amplifier at 30 mK. These temperatures maintain superconductivity and prevent thermal noise from disrupting the delicate quantum states. The flux sensing and control lines that interact with the qubits are also cooled down to 1 K to ensure minimal noise and stable control of the quantum operations. The classical control components, such as the microwave photon source, SMU, ADC, DAC, and HPC cluster, operate at room temperature (around 293 K). These components handle the classical data processing and control signals that drive the quantum system.

Via the tunable signal control and classical monitoring feedback loop, the system effectively mitigates noise, ensuring that the signals interacting with the qubits are phase-aligned and coherent throughout the gate operations. The cryogenic placement of the tunable components 1006 minimizes thermal noise and drift, further enhancing the system's ability to maintain coherence. The combination of real-time control and error monitoring by the classical node ensures that qubits remain stable during computation, resulting in higher-fidelity quantum gate operations and improved overall performance of the quantum system. The technology described herein thus overcomes a significant challenge in quantum computing, namely preserving qubit coherence and reducing errors during quantum operations.

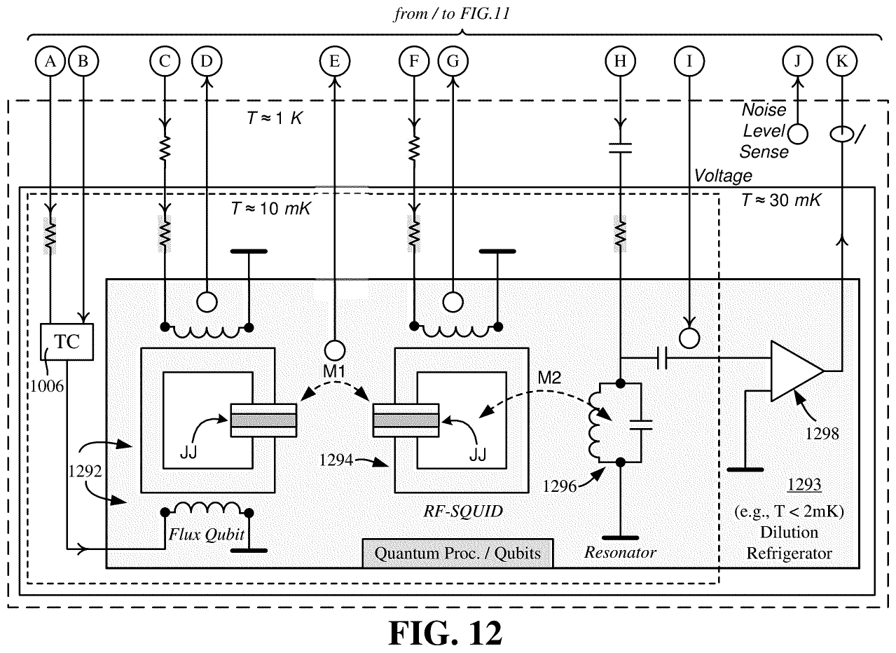

FIGS. 11 and 12 comprise a block diagram representation of an example quantum processor measurement and control setup/environment, in which qubit control and readout is facilitated by integrating a classical high-performance computing server/cluster 1180 (FIG. 11) with a quantum computing system having a quantum processor and qubits 1292 (FIG. 12) near the base plate of a dilution refrigerator 1293, on the order of 2 milli-Kelvin (mk).

The representation of FIG. 12 thus shows an example architecture of a quantum system with a focus on cryogenic control and signal processing. The overall system (e.g., summarized in FIG. 10) integrates classical control components (FIG. 11) and quantum hardware (FIG. 12) to ensure the proper manipulation and measurement of qubits, with an emphasis on temperature management to maintain the coherence of quantum operations. As generally shown in FIG. 12, the quantum hardware is housed within the dilution refrigerator 1293, ensuring ultra-low temperatures for stable qubit operations. In one implementation, the quantum portion (FIG. 12) of the hybrid system 1000 (FIG. 10) operates with a combination of flux qubits, RF-SQUIDs (radio frequency-superconducting quantum interference devices), and a resonator, each contributing to the manipulation and control of quantum states.

In general, a flux qubit is a type of qubit that operates based on superconducting loops in which the current can circulate in both clockwise and counterclockwise directions, representing quantum superposition. The qubit (e.g., 1292) is housed at a temperature of 10 mK or below (e.g., 2-4 mK), which helps maintain coherences and prevent decoherence due to thermal noise.

The RF-SQUIDs are superconducting circuits used to control the coupling between qubits. The RF-SQUIDs allow manipulation of quantum states by providing a tunable inductive coupling between the qubits. The Josephson junctions (JJ) in the RF-SQUIDs enable quantum tunneling, which is a core part of quantum operations in superconducting qubits. The magnetic interaction between the RF-SQUIDs (represented by M1), and between the RF-SQUID 1294 and the resonator 1296 (represented by M2), can adjust the energy levels and state transitions of the qubits.

The resonator 1296 is coupled to the qubits, providing a device to read out the qubit states. By measuring the resonance frequency shifts, the state of the qubits can be inferred, allowing for quantum state measurements. After interacting with the qubits, the signal is passed through a cryogenic amplifier 1298, e.g., operating at around 30 mK. Amplifying the signal in such a low-temperature environment ensures that noise is kept to a minimum before the signal is sent for classical processing. The amplifier 1298 helps to boost the weak quantum signals for subsequent measurement without introducing significant noise that could affect accuracy.

As shown in FIG. 11, the example classical (non-quantum) portion of the hybrid system 1000 (FIG. 10) includes the microwave photon source 1002, which is controlled by the classical high-performance compute (HPC) server/cluster 1180, both operating at room temperature (around 293 K). As described herein, the classical system portion interfaces with the quantum hardware to drive, control, and measure qubit operations. M ore particularly and as will be understood, the server/cluster 1180 processes the data from the quantum hardware, including measurements from the qubits, and can also provide real-time feedback for qubit control, adjusting the parameters, including the tunable components 1006 (e.g., the bandpass filter 1016), based on the measured outcomes to optimize the quantum operations.

The microwave photon source 1004 generates microwave signals that interact with the qubits. The microwave source 1004 feeds microwave signals through coaxial cables into the quantum hardware. The microwave signals are controlled to ensure precise phase, amplitude, and timing, as is appropriate for quantum gate operations. The microwave photons from the microwave photon source 1004 go through multiple temperature stages to reach the flux qubits (e.g., 1292) in the dilution refrigerator 1293.

At each stage, along with the reducing temperature, the microwave signal is heavily attenuated as qubits are provided very low-power microwave photons. Note that the HPC server/cluster 1180 can control operation of the photon source 1004 in terms of pulses, e.g., the sequence of pulses, the width and voltage of the pulses and the like can be controlled by the classical server/cluster 1180; any amount of gates can be applied to the qubit, to control the qubit and configure the qubit, including as described herein.

A qubit bias control component (block 1181, FIG. 11) provides precise magnetic flux control to the qubits. Adjusting the magnetic flux through the superconducting loops enables the fine-tuning of the qubit states. This control system operates at room temperature but communicates with the cryogenic quantum hardware through superconducting lines. The qubit bias control can be in the form of a constant voltage or current to adjust the energy levels of the qubit, and can be provided from the classical HPC server/cluster 1180. A change in the magnetic flux in the qubit 1292 (FIG. 12, after absorption of a photon) induces a change in the mutual flux coupling (M1) with an RF-SQUID M2, which in general acts as a detector controlled by the server/cluster 1180, e.g., via a digital-to-analog converter (DAC) 1182. The RF-SQUID 1292 includes a superconducting loop across a Josephson Junction (JJ) characterized by its critical current (IC), capacitance (C), and shunt resistance (R).

Note that in general, the digital-to-analog converter 1182 along with an analog-to-digital converter (ADC) 1183 translates between the digital signals used for classical computation and the analog signals used in the quantum hardware. The DAC 1182 generates precise analog control signals for driving qubit operations, while the ADC 1183 digitizes the analog signals received from the qubit measurement. These converters operate at room temperature in this example.

To register signals in RF-SQUIDs, a readout resonator/LC (inductor-capacitor) tank circuit 1296 (FIG. 12) is used, including an inductor (L_{T}) and a capacitor (C_{T}), which together oscillate at a natural frequency ω_{T}/2π=½π\sqrt{(L_{T}C_{T})}. The resonator 1296 is designed to be sensitive to small changes in magnetic flux, mutually coupled (M2) to the RF-SQUID 1294, as appropriate for detecting photon interactions with the qubit. An external pumping current I_{rf} sin(ω_{P}t) is provided (via labeled circle “G”) from a detector/generator 1184 (FIG. 11) at frequency Ω/2π, which is very close to the natural frequency of the LC tank circuit resonator 1296 (ω_{P}−ω_{T})/ω_{T}<<1 and quality factor Q>>1. The current/voltage bias to the RF-SQUID 1296 is very accurate so as not to (inadvertently) operate the RF-SQUID M2 in non-hysteresis mode.

Note that FIG. 12 only shows components for two RF-SQUIDS/qubits, however any practical number may be present in a given quantum computing configuration. Further note that the resonator 1296 can obtain a control signal, and because any voltage generates the magnetic flux, a qubit state change will occur, as the generated magnetic flux will break the entanglement, or it will collapse the qubit; the system can read that what was the recent data, such as how much frequency changed in the resonator 1296.

The output from the LC tank/resonator 1296 is very weak, and hence is amplified (signal amplifier 1298) and provided to the detector 1184 (FIG. 11), which further performs threshold filtering (block 1185) to quantize the state of the qubit, and provides the transistor-transistor logic (TTL) trigger (block 1186) to the classical server/cluster 1180. In general, threshold filtering component, block 1185, along with the detector 1184, are part of the classical control system and fed to the PCIe interface, and are responsible for analyzing the output from the quantum hardware. The signals are passed through the threshold filter to remove noise and isolate the meaningful quantum information. The detector 1184 then extracts the final measurement results from the filtered signals. The TTL trigger 1186 is used for synchronizing operations within the classical system and with the quantum hardware. Precise timing of signals is used in quantum systems, and the TTL trigger 1186 ensures that operations such as qubit state initialization, manipulation, and readout are synchronized.

To ensure accurate control, a PCIe card interface-based digital source measure unit (SMU) 1188 can be used, such as a high-performance SM U that is commercially available. In general, a digital source measure unit (SM U) 1188 provides precise voltage or current control for various elements in the quantum system. The SM U 1188 ensures that bias voltages and other control parameters are stable, which maintains qubit fidelity. A high-performance PXI-based SMU (PCI eXtensions for Instrumentation) provides fast, precise dynamic measurements from DC to a 20 μs pulse, with outputs up to 210 V/315 mA, 10 femtoampere (fA) resolution, and the lowest source noise.

Similarly, a commercially available PXI-based digital-to-analog converter (DAC) 1182 can be used, such as one that features sixteen simultaneous channels capable of supplying stimulus waveforms with output voltages ranging from 0V to +30V, and output currents from 0 mA to +20 mA. In one implementation, both the SM U 1188 and DAC 1182 are compatible with PCIe interfaces and can be housed in a PXI chassis, which saves rack space and reduces maintenance cost. Also shown in FIG. 11 is the analog-to-digital converter (ADC) 1183 coupled to the classical server/cluster 1112 and a number of sensors (the small circles at various tap points in FIG. 12, corresponding to the circled labels D, E, G, I and J).

To summarize, in one example implementation, the digital SMU 1188 can control tunable components 1006 (FIGS. 10-12, including the bandpass filter 1016) that can apply a filtered microwave signal to a qubit. Feedback information (block 1189, FIG. 11) can be provided to the classical server/cluster 1112. Such feedback information allows real-time tuning and repeated measurements to ensure accurate quantum state tracking and error correction, e.g., if small deviations are detected between the applied signal and the measured signal following execution of one or more operations on the qubit as described herein, the signal can be adjusted and the operations reattempted and remeasured.

Thus, as generally represented in FIG. 11, hardware for control and readout can, for example, include one or more advanced source measure units (SM Us) and analog-to-digital converters (ADCs), which can be managed more efficiently with classical systems, thereby reducing the number of physical components and vendor equipment otherwise needed. Such a hybrid system can be designed modularly, where each module, including multiple qubits and their respective control/readout lines, can be independently managed by one or more classical processors. Such modularity simplifies system scaling, allowing new modules to be added without redesigning the entire control infrastructure.

The technology described herein leverages the precise classical control of the qubit control and measurement operations. For example, a classical high-performance computing server (or cluster of such servers) with peripheral component interconnect express (PCIe-based) or the like control can use a source measure unit (SMU) for quantum computers with some practical number (e.g., one the order of dozens) of qubits, including to apply controlled phase shift, controlled bandpass filtering, and controlled rotation to a qubit.

Further, the technology described herein controls the qubit readout circuit using a source measure unit and digital-to-analog converter; this can provide ultra-precise control of readouts with ultra-low signals. The hybrid classical-quantum technology described herein is, in part, directed to recording a photon-induced transition in a flux qubit, for example. Note however that photons/flux qubits are only examples, as indeed, the technology described herein is agnostic to any particular type of qubit, and further, that probe signals other than those based on microwave photons can be used, as appropriate for a given type of qubit.

Further, in one or more example implementations, a bandpass filter 1016 can be designed and monolithically integrated with a superconducting chip that integrates the qubits. FIG. 13 is a block diagram representation of an example quantum processor measurement and control setup/system 1340 including a measurement and control setup for a superconducting quantum computing chip 1342 near the base plate of a dilution refrigerator 1343, on the order of 2-10 Kelvin (mK). Some number of qubits 1346(1)-1346(n) (four are depicted, but any practical number may be present) are fabricated on the superconducting quantum computing chip 1342, along with a monolithically integrated bandpass filter (BPF) 1016. Note that the other tunable components 1006 (FIG. 10, including the phase shifter 1012 and/or the bandstop filter 1018) also can be similarly fabricated on the superconducting quantum computing chip 1342.

Also shown in FIG. 13 as part of the qubit measuring portion are circulators 1348 and 1350, a Josephson parametric amplifier (JPA) 1352, an isolator 1354 and a high electron mobility transistor (HEMT) G. In general, a probe signal that is a set of strongly attenuated microwave tones (<−120 dBm) is by injected via coaxial cables (depicted as unshaded cylinders) and attenuators to the qubits 1346(1)-1346(n) through the various levels of the quantum processor system 1340, resulting in a measurement signal being input via a readout line to a first port of the circulator 1348. As described herein, the circulator 1348 is configured for clockwise rotation, whereby the signal is routed to a second port (low insertion loss) and not the third port (high isolation, and coupled via resistor to ground), nor returned to the first port (low return loss). The second port is coupled to the input port of a second circulator 1350 configured for counterclockwise rotation, such that the signal is routed to at least one Josephson parametric amplifier (JPA) 1352, with the amplified measurement signal routed back to the output port of the circulator 1350 though the isolator 1354 to the HEMT G for further gain before measurement by one or more conventional RF devices (not explicitly shown). Note that the shaded cylinder shown in the measurement signal output path represents a superconducting coaxial cable. Based on the measurement results, qubit control signals can be sent to the qubits 1346(1)-1346(n).

Thus, each circulator is a nonreciprocal three-port device that allows signals to travel in only one predetermined direction among its three ports, whereby the qubit readout line uses such circulators 1348 and 1350 to provide isolation between different components so as to maintain the fidelity of the qubit readout. By isolating different parts of the readout circuit, circulators help in reducing noise that could otherwise affect the qubit's state and/or the accuracy of the readout. Multiple circulators are used in the quantum computing setup, ensuring that signals are correctly channeled to the appropriate destinations as shown in FIG. 13.

To summarize FIG. 13, the state of the superconducting qubits is probed, and the readout involves amplifying and delivering the measured result back to room temperature. The weak output signal from a qubit is amplified using one or more superconducting parametric amplifiers, such as Josephson parametric amplifiers (JPA), operating at 10 mK and semiconductor high electron mobility transistor (HEMT) amplifiers operating at 4 K. The RF circulators are used to protect the quantum circuit from reflections and noise; the probing, control, and readout of qubit systems involves a large amount of microwave hardware.

One or more example implementations and embodiments can be embodied in a tunable bandpass filter, such as described and represented herein. The tunable bandpass filter can include a first microstrip inductor, and a first radio-frequency superconducting quantum interference device (RF-SQUID) set; the first RF-SQUID set can be inductively coupled to the first inductor and inductively coupled to a direct current (DC) control line. The tunable bandpass filter can include a second microstrip inductor, and a second RF-SQUID set; the second RF-SQUID set can be inductively coupled to the second inductor and inductively coupled to the DC control line. The tunable bandpass filter can include a group of capacitors electrically coupled to the first microstrip inductor and the second microstrip inductor. An amount of voltage applied to the DC control line can inductively couple a first amount of magnetic flux to the first RF-SQUID set, to determine a first controlled inductance of the first microstrip inductor. The amount of voltage applied to the DC control line can inductively couple a second amount of magnetic flux to the second RF-SQUID set, to determine a second controlled inductance of the second microstrip inductor. A radio frequency (RF) signal input to the tunable bandpass filter can result in a filtered instance of the RF signal output from the tunable bandpass filter, within a controlled frequency range based on capacitance values of the group of capacitors, the first controlled inductance of the first microstrip inductor, and the second controlled inductance of the second microstrip inductor.

The RF signal can include a microwave signal, from a microwave signal source, directed towards a qubit chain.

The tunable bandpass filter and the qubit chain can be deployed within a dilution refrigerator.

The tunable bandpass filter and at least one qubit of the qubit chain can be fabricated on a single chip.

The tunable bandpass filter and the microwave signal source can be deployed at about 70 degrees Fahrenheit.

The group of capacitors can include five capacitors configured as a five-pole tunable bandpass filter.

The first microstrip inductor can be coupled between a first conductor and a ground, the second microstrip inductor can be coupled between a second conductor and the ground, and the group of capacitors can include a first capacitor that can include a first capacitor end coupled to the ground, and a second capacitor end coupled to the first conductor, a second capacitor that can include a third capacitor end coupled to the ground, and a fourth capacitor end coupled to the second conductor, a third capacitor that can include a fifth capacitor end terminated by a first resistor to ground, and a sixth capacitor end coupled to the first conductor, a fourth capacitor that can include a seventh capacitor end coupled to the first conductor, and an eighth capacitor end coupled to the second conductor, and a fifth capacitor that can include a ninth capacitor end terminated by a second resistor to ground, and a tenth capacitor end coupled to the second conductor.

Respective capacitors of the group of capacitors can include respective multilayer metal-insulator-metal capacitors.

Layers of the respective multilayer metal-insulator-metal capacitors can include niobium superconducting layers.

The amount of voltage applied to the DC control line can be controlled by a controller.

The controller can include a computing device that can include at least one processor and at least one memory.

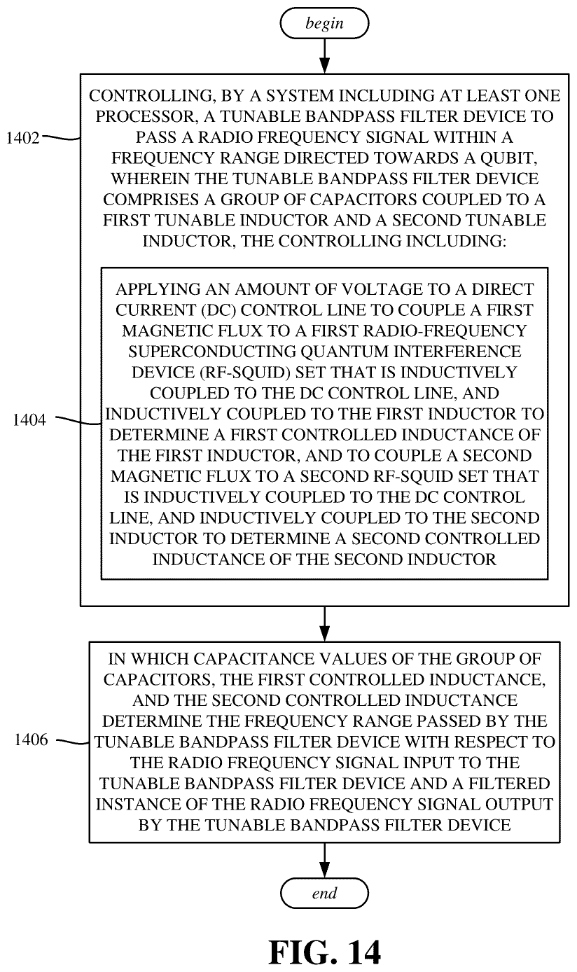

One or more example implementations and embodiments, such as corresponding to example operations of a method, can be represented in FIG. 14. Example operation 1402 represents controlling, by a system including at least one processor, a tunable bandpass filter device to pass a radio frequency signal within a frequency range directed towards a qubit, wherein the tunable bandpass filter device can include a group of capacitors coupled to a first tunable inductor and a second tunable inductor. Controlling the tunable bandpass filter device can include example operation 1404, which represents applying an amount of voltage to a direct current (DC) control line to couple a first magnetic flux to a first radio-frequency superconducting quantum interference device (RF-SQUID) set that can be inductively coupled to the DC control line, and inductively coupled to the first inductor to determine a first controlled inductance of the first inductor, and to couple a second magnetic flux to a second RF-SQUID set that can be inductively coupled to the DC control line, and inductively coupled to the second inductor to determine a second controlled inductance of the second inductor. Example block 1406 represents that capacitance values of the group of capacitors, the first controlled inductance, and the second controlled inductance determine the frequency range passed by the tunable bandpass filter device with respect to the radio frequency signal input to the tunable bandpass filter device and a filtered instance of the radio frequency signal output by the tunable bandpass filter device.

The radio frequency signal can include a microwave signal directed towards a qubit, and controlling the tunable bandpass filter device can be performed by a computing device that monitors interaction of the microwave signal with the qubit.

The filtered instance of the radio frequency signal can be a first filtered instance, the radio frequency signal can be a first microwave signal directed towards a qubit, the frequency range passed by the tunable bandpass filter device can be a first frequency range, applying the amount of voltage can be a first applying of a first amount of voltage, and controlling the tunable bandpass filter device can be a first controlling operation to filter the first microwave signal directed towards the qubit. Further operations can include in a second controlling operation, controlling, by the system, the tunable bandpass filter device to pass a second microwave signal within a second tunable frequency range directed towards the qubit, the second controlling operation including applying a second amount of voltage to the DC control line to couple a third magnetic flux to the first RF-SQUID set to determine a third controlled inductance of the first inductor, and to couple a fourth magnetic flux to the second RF-SQUID set to determine a fourth controlled inductance of the second inductor; the capacitance values of the group of capacitors, the third controlled inductance, and the fourth controlled inductance determine the second tunable frequency range passed by the tunable bandpass filter device with respect to a second microwave signal input to the tunable bandpass filter device and a second filtered instance of the second microwave signal output by the tunable bandpass filter device.

The second controlling operation can be based on monitoring, by the system, interaction of the first filtered instance of the first microwave signal with the qubit to determine the second tunable frequency range used for filtering the second microwave signal.

One or more example implementations and embodiments can be embodied in a system, such as described and represented herein; the system can include a cryogenic tunable bandpass filter device. The cryogenic tunable bandpass filter device can include a group of capacitors, a first microstrip inductor electrically coupled to the group of capacitors, and a second microstrip inductor electrically coupled to the group of capacitors. The cryogenic tunable bandpass filter device can include a first RF-SQUID set inductively coupled to the first microstrip inductor, a second RF-SQUID set inductively coupled to the second microstrip inductor and a DC control line inductively coupled to the first RF-SQUID set, and inductively coupled to the second RF-SQUID set. The system can include a controller configured to apply voltage to the DC control line, in which a controlled amount of voltage applied by the controller to the first DC control line determines a first RF-SQUID set inductance, resulting in a first controlled inductance of the first microstrip inductor, and determines a second RF-SQUID set inductance, resulting in a second controlled inductance of the second microstrip inductor. A microwave signal input to the cryogenic tunable bandpass filter results in a filtered instance of the microwave signal output from the cryogenic tunable bandpass filter, within a controlled frequency range based on capacitance values of the group of capacitors, the first controlled inductance of the first microstrip inductor, and the second controlled inductance of the second microstrip inductor.

The microwave signal can be generated by a microwave signal source controlled by the controller, and the cryogenic tunable bandpass filter can be coupled via an input contact to the microwave signal source to obtain the microwave signal, and coupled via an output contact to output the filtered instance of the microwave signal to a qubit of a quantum processor.

The input contact can be coupled to the microwave signal source via a phase shifter to obtain the microwave signal as a phase-shifted microwave signal.

The cryogenic tunable bandpass filter can be deployed within a dilution refrigerator at a temperature level of five Kelvin or below.

The microwave signal can be a first microwave signal, the filtered instance of the first microwave signal can be a first filtered instance, wherein controlled amount of voltage can be a first controlled amount of voltage, the controlled frequency range can be a first controlled frequency range. The cryogenic tunable bandpass filter can be configured to obtain a second microwave signal; a second controlled amount of voltage applied to the DC control line can determine a third RF-SQUID set inductance, resulting in a third controlled inductance of the first microstrip inductor, and can determine a fourth RF-SQUID set inductance, resulting in a fourth controlled inductance of the second microstrip inductor. A second microwave signal input to the cryogenic tunable bandpass filter can result in a second filtered instance of the second microwave signal output from the cryogenic tunable bandpass filter, within a second controlled frequency range, based on the capacitance values of the group of capacitors, the third controlled inductance of the first microstrip inductor, and the third controlled inductance of the second microstrip inductor.

As can be seen, the technology described herein includes a tunable bandpass filter with a frequency response achieved via rf-SQUIDs. The bandpass filter's inductors can be tunable using controlled voltage to a control line inductively coupled to rf-SQUIDs, which allow DC voltage/current-controlled fine-tuning of the frequency response. This adaptability allows the filter's frequency response to be fine-tuned to adapt to environmental changes or fabrication variations that might affect the qubit's operating frequencies.

Unlike conventional waveguide-based bandpass filters that require external interfaces and increase complexity, the bandpass filter described herein can be designed for monolithic integration, including integration with qubits on the same chip. This integration significantly reduces signal losses due to elimination of external interconnects and enhances the system reliability by simplifying assembly complexity.

The use of a multi-layer superconducting fabrication process employing eight layers of Niobium or the like efficiently packs the capacitors and inductors while maintaining performance. The multilayer capacitor design, combined with microstrip inductors, achieves a compact footprint beneficial for quantum computers, which also helps to ensure minimal thermal load on the cryogenic system, which is an issue with conventional bandpass filters.

In one example implementation, the classical control system described herein, including the ADC, DAC, and HPC server/cluster, can monitor the quantum operations in real-time, to dynamically adjust control parameters based on feedback from the qubits, and thereby mitigate noise and optimize qubit performance without introducing additional noise or latency. This is in contrast to traditional designs for control in quantum circuits that do not adapt to dynamic changes in the quantum environment. Indeed, as errors develop over time, existing systems do not provide real-time adjustments to compensate for noise-related or other types of deviations, which causes the quantum system's performance to degrade over extended operations; qubit operations in existing systems are vulnerable to noise and signal drift, as errors are only reactively corrected after they have already adversely impacted the system. Instead, the technology described herein enables real-time detection and correction of signal issues including misalignments and noise outside of a desired frequency band, mitigating noise-related errors, which results in enhanced qubit coherence and improved fidelity in quantum gate operations.

The above description of illustrated embodiments of the subject disclosure, comprising what is described in the Abstract, is not intended to be exhaustive or to limit the disclosed embodiments to the precise forms disclosed. While specific embodiments and examples are described herein for illustrative purposes, various modifications are possible that are considered within the scope of such embodiments and examples, as those skilled in the relevant art can recognize.

In this regard, while the disclosed subject matter has been described in connection with various embodiments and corresponding Figures, where applicable, it is to be understood that other similar embodiments can be used or modifications and additions can be made to the described embodiments for performing the same, similar, alternative, or substitute function of the disclosed subject matter without deviating therefrom. Therefore, the disclosed subject matter should not be limited to any single embodiment described herein, but rather should be construed in breadth and scope in accordance with the appended claims below.

As used in this application, the terms “component,” “system,” “platform,” “layer,” “selector,” “interface,” and the like are intended to refer to a computer-related resource or an entity related to an operational apparatus with one or more specific functionalities, wherein the entity can be either hardware, a combination of hardware and software, software, or software in execution. As an example, a component can be an apparatus with specific functionality provided by mechanical parts operated by electric or electronic circuitry. As yet another example, a component can be an apparatus that provides specific functionality through electronic components without mechanical parts, the electronic components can comprise a processor therein to execute software or firmware that confers at least in part the functionality of the electronic components.

In addition, the term “or” is intended to mean an inclusive “or” rather than an exclusive “or.” That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances.

While the embodiments are susceptible to various modifications and alternative constructions, certain illustrated implementations thereof are shown in the drawings and have been described above in detail. It should be understood, however, that there is no intention to limit the various embodiments to the specific forms disclosed, but on the contrary, the intention is to cover all modifications, alternative constructions, and equivalents falling within the spirit and scope.

In addition to the various implementations described herein, it is to be understood that other similar implementations can be used or modifications and additions can be made to the described implementation(s) for performing the same or equivalent function of the corresponding implementation(s) without deviating therefrom. Still further, multiple processing chips or multiple devices can share the performance of one or more functions described herein, and similarly, storage can be effected across a plurality of devices. Accordingly, the various embodiments are not to be limited to any single implementation, but rather are to be construed in breadth, spirit and scope in accordance with the appended claims.

1. A tunable bandpass filter, comprising:
a first microstrip inductor;
a first radio-frequency superconducting quantum interference device (RF-SQUID) set, the first RF-SQUID set being inductively coupled to the first inductor and inductively coupled to a direct current (DC) control line;
a second microstrip inductor;
a second RF-SQUID set, the second RF-SQUID set being inductively coupled to the second inductor and inductively coupled to the DC control line; and
a group of capacitors electrically coupled to the first microstrip inductor and the second microstrip inductor,
wherein an amount of voltage applied to the DC control line inductively couples a first amount of magnetic flux to the first RF-SQUID set, to determine a first controlled inductance of the first microstrip inductor,
wherein the amount of voltage applied to the DC control line inductively couples a second amount of magnetic flux to the second RF-SQUID set, to determine a second controlled inductance of the second microstrip inductor, and
wherein a radio frequency (RF) signal input to the tunable bandpass filter results in a filtered instance of the RF signal output from the tunable bandpass filter, within a controlled frequency range based on capacitance values of the group of capacitors, the first controlled inductance of the first microstrip inductor, and the second controlled inductance of the second microstrip inductor.

2. The tunable bandpass filter of claim 1, wherein the RF signal comprises a microwave signal, from a microwave signal source, directed towards a qubit chain.

3. The tunable bandpass filter of claim 2, wherein the tunable bandpass filter and the qubit chain are deployed within a dilution refrigerator.

4. The tunable bandpass filter of claim 2, wherein the tunable bandpass filter and at least one qubit of the qubit chain are fabricated on a single chip.

5. The tunable bandpass filter of claim 2, wherein the tunable bandpass filter and the microwave signal source are deployed at about 70 degrees Fahrenheit.

6. The tunable bandpass filter of claim 1, wherein the group of capacitors comprises five capacitors configured as a five-pole tunable bandpass filter.

7. The tunable bandpass filter of claim 1, wherein the first microstrip inductor is coupled between a first conductor and a ground, wherein the second microstrip inductor is coupled between a second conductor and the ground, and wherein the group of capacitors comprises:
a first capacitor comprising a first capacitor end coupled to the ground, and a second capacitor end coupled to the first conductor,
a second capacitor comprising a third capacitor end coupled to the ground, and a fourth capacitor end coupled to the second conductor,
a third capacitor comprising a fifth capacitor end terminated by a first resistor to ground, and a sixth capacitor end coupled to the first conductor,
a fourth capacitor comprising a seventh capacitor end coupled to the first conductor, and an eighth capacitor end coupled to the second conductor, and
a fifth capacitor comprising a ninth capacitor end terminated by a second resistor to ground, and a tenth capacitor end coupled to the second conductor.

8. The tunable bandpass filter of claim 1, wherein respective capacitors of the group of capacitors comprise respective multilayer metal-insulator-metal capacitors.

9. The tunable bandpass filter of claim 8, wherein layers of the respective multilayer metal-insulator-metal capacitors comprise niobium superconducting layers.

10. The tunable bandpass filter of claim 1, wherein the amount of voltage applied to the DC control line is controlled by a controller.

11. The tunable bandpass filter of claim 10, wherein the controller comprises a computing device comprising at least one processor and at least one memory.

12. A method, comprising:
controlling, by a system comprising at least one processor, a tunable bandpass filter device to pass a radio frequency signal within a frequency range directed towards a qubit, wherein the tunable bandpass filter device comprises a group of capacitors coupled to a first tunable inductor and a second tunable inductor, the controlling comprising:
applying an amount of voltage to a direct current (DC) control line to couple a first magnetic flux to a first radio-frequency superconducting quantum interference device (RF-SQUID) set that is inductively coupled to the DC control line, and inductively coupled to the first inductor to determine a first controlled inductance of the first inductor, and to couple a second magnetic flux to a second RF-SQUID set that is inductively coupled to the DC control line, and inductively coupled to the second inductor to determine a second controlled inductance of the second inductor,
wherein capacitance values of the group of capacitors, the first controlled inductance, and the second controlled inductance determine the frequency range passed by the tunable bandpass filter device with respect to the radio frequency signal input to the tunable bandpass filter device and a filtered instance of the radio frequency signal output by the tunable bandpass filter device.

13. The method of claim 12, wherein the radio frequency signal comprises a microwave signal directed towards a qubit, and wherein the controlling of the tunable bandpass filter device is performed by a computing device that monitors interaction of the microwave signal with the qubit.

14. The method of claim 12, wherein the filtered instance of the radio frequency signal is a first filtered instance, wherein the radio frequency signal is a first microwave signal directed towards a qubit, wherein the frequency range passed by the tunable bandpass filter device is a first frequency range, wherein the applying of the amount of voltage is a first applying of a first amount of voltage, wherein the controlling of the tunable bandpass filter device is a first controlling operation to filter the first microwave signal directed towards the qubit, and further comprising:
in a second controlling operation, controlling, by the system, the tunable bandpass filter device to pass a second microwave signal within a second tunable frequency range directed towards the qubit, the second controlling operation comprising:
applying a second amount of voltage to the DC control line to couple a third magnetic flux to the first RF-SQUID set to determine a third controlled inductance of the first inductor, and to couple a fourth magnetic flux to the second RF-SQUID set to determine a fourth controlled inductance of the second inductor,
wherein the capacitance values of the group of capacitors, the third controlled inductance, and the fourth controlled inductance determine the second tunable frequency range passed by the tunable bandpass filter device with respect to a second microwave signal input to the tunable bandpass filter device and a second filtered instance of the second microwave signal output by the tunable bandpass filter device.

15. The method of claim 14, wherein the second controlling operation is based on monitoring, by the system, interaction of the first filtered instance of the first microwave signal with the qubit to determine the second tunable frequency range used for filtering the second microwave signal.

16. A system, comprising:
a cryogenic tunable bandpass filter device, comprising:
a group of capacitors,
a first microstrip inductor electrically coupled to the group of capacitors;
a second microstrip inductor electrically coupled to the group of capacitors;
a first radio-frequency superconducting quantum interference device (RF-SQUID) set inductively coupled to the first microstrip inductor;
a second RF-SQUID set inductively coupled to the second microstrip inductor;
a direct current (DC) control line inductively coupled to the first RF-SQUID set, and inductively coupled to the second RF-SQUID set; and
a controller configured to apply voltage to the DC control line,
wherein a controlled amount of voltage applied by the controller to the first DC control line determines a first RF-SQUID set inductance, resulting in a first controlled inductance of the first microstrip inductor, and determines a second RF-SQUID set inductance, resulting in a second controlled inductance of the second microstrip inductor,
wherein a microwave signal input to the cryogenic tunable bandpass filter results in a filtered instance of the microwave signal output from the cryogenic tunable bandpass filter, within a controlled frequency range based on capacitance values of the group of capacitors, the first controlled inductance of the first microstrip inductor, and the second controlled inductance of the second microstrip inductor.

17. The system of claim 16, wherein the microwave signal is generated by a microwave signal source controlled by the controller, and wherein the cryogenic tunable bandpass filter is coupled via an input contact to the microwave signal source to obtain the microwave signal, and coupled via an output contact to output the filtered instance of the microwave signal to a qubit of a quantum processor.

18. The system of claim 17, wherein the input contact is coupled to the microwave signal source via a phase shifter to obtain the microwave signal as a phase-shifted microwave signal.

19. The system of claim 16, wherein the cryogenic tunable bandpass filter is deployed within a dilution refrigerator at a temperature level of five Kelvin or below.

20. The system of claim 16, wherein the microwave signal is a first microwave signal, wherein the filtered instance of the first microwave signal is a first filtered instance, wherein the controlled amount of voltage is a first controlled amount of voltage, wherein the controlled frequency range is a first controlled frequency range,
wherein the cryogenic tunable bandpass filter is configured to obtain a second microwave signal,
wherein a second controlled amount of voltage applied to the DC control line determines a third RF-SQUID set inductance, resulting in a third controlled inductance of the first microstrip inductor, and determines a fourth RF-SQUID set inductance, resulting in a fourth controlled inductance of the second microstrip inductor, and
wherein a second microwave signal input to the cryogenic tunable bandpass filter results in a second filtered instance of the second microwave signal output from the cryogenic tunable bandpass filter, within a second controlled frequency range, based on the capacitance values of the group of capacitors, the third controlled inductance of the first microstrip inductor, and the third controlled inductance of the second microstrip inductor.
